(19) United States
(12) Patent Application Publication
(10) Pub. No.: US 2025/0143108 A1
(43) Pub. Date: May 1, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Pan ZHAO, Beijing (CN); Zhiliang JIANG, Beijing (CN); Ziyang YU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/682,939

(22) PCT Filed: May 20, 2022
(86) PCT No.: PCT/CN2022/094197

§ 371 Date: Feb. 12, 2024

(51) Int. Cl. H10K 59/131

(52) U.S. Cl. CPC H10K 59/131

(57) ABSTRACT

The present disclosure relates to a display panel with a display area, a first non-display area and a second non-display area are correspondingly disposed on opposite sides of the display area in a first direction, and a binding area is disposed on a side of the second non-display area away from the display area. The display panel includes: a first wire, disposed in the display area and extending along the first direction, wherein the first wire is electrically coupled to a plurality of pixels arranged along the first direction; a second wire, extending along the first direction and extending from the display area to the first non-display area, the second non-display area and the binding area; a connection wire, disposed in the first non-display area and coupled between the first wire and the second wire; and a binding pin, disposed in the binding area and coupled to the second wire.

### CROSS-REFERENCE

The present application is a U.S. National Stage of International Application No. PCT/CN2022/094197, filed on May 20, 2022, the contents of which are incorporated herein by reference in their entireties for all purposes.

### TECHNICAL FIELD

The present disclosure relates to the field of display technologies, and in particular, to a display panel and a display device.

### BACKGROUND

With the development of technologies, customers have increasingly demanding requirements for display products, thereby constantly promoting to improve screen-to-body ratios and pixel densities of the display products. In order to increase the screen-to-body ratios, it is imperative to narrow bezels of the display products.

It should be noted that the information disclosed in the Background section above is only for enhancing the understanding of the background of the present disclosure, and thus may include information that does not constitute prior art known to those of ordinary skill in the art.

### SUMMARY

The present disclosure provides a display panel and a display device.

According to an aspect of the present disclosure, there is provided a display panel with a display area, a first non-display area and a second non-display area are correspondingly disposed on opposite sides of the display area in a first direction, and a binding area is disposed on a side of the second non-display area away from the display area, wherein the display panel includes:
a first wire, disposed in the display area and extending along the first direction, wherein the first wire is electrically coupled to a plurality of pixels arranged along the first direction;
a second wire, extending along the first direction and extending from the display area to the first non-display area, the second non-display area and the binding area;
a connection wire, disposed in the first non-display area and coupled between the first wire and the second wire; and
a binding pin, disposed in the binding area and coupled to the second wire.

According to another aspect of the present disclosure, there is provided a display device, including the display panel according to any one of the above embodiments.

It should be noted that the above general description and the following detailed description are merely exemplary and explanatory and should not be construed as limiting of the disclosure.

### BRIEF DESCRIPTION OF THE DRAWINGS

The drawings here are incorporated into the specification and constitute a part of the specification, show embodiments in consistent with the present disclosure, and are used together with the specification to explain principles of the present disclosure. Obviously, the drawings in the following description are only some embodiments of the present disclosure. For those of ordinary skill in the art, other drawings can be obtained based on these drawings without creative work.

FIG. 1 is a schematic structural diagram of an area division of a display panel according to an embodiment of the present disclosure.

FIG. 2 is a schematic structural diagram of the display panel in FIG. 1 after being bent.

FIG. 3 is a schematic structural diagram of a wiring structure of the display panel in FIG. 1 according to an embodiment of the present disclosure.

FIG. 4 is a schematic cross-sectional view of the display panel in FIG. 3 sectioned at a transistor according to an embodiment of the present disclosure.

FIG. 5 is a schematic cross-sectional view of the display panel in FIG. 3 sectioned along a connection wire.

FIG. 6 is a schematic structural diagram of a wire layout and an equivalent circuit of a display panel according to an embodiment of the present disclosure.

FIG. 7 is a schematic cross-sectional view of a display panel sectioned at a transistor according to another embodiment of the present disclosure.

FIG. 8 is a schematic structural diagram of a wiring structure of a display panel in the related arts.

Description of reference signs:
1. Base substrate; 2. Light shielding layer; 3. Buffer layer; 4. Active layer; 5. Gate insulation layer;
61. First gate layer; 611. Gate; 612. Connection wire; 613. Gate line; 614. First capacitor pole piece;
62. Second gate layer;
71. First insulation layer; 711. First via hole; 712. Second via hole; 713. Fourth via hole;
72. Second insulation layer; 721. Third via hole; 722. Fifth via hole;
73. Third insulation layer; 731. Seventh via hole; 732. Eighth via hole;
74. Fourth insulation layer; 741. Sixth via hole;
81. First source-drain layer; 811. First wire; 812. Drain; 813. Source; 814. Third wire; 815. Second capacitor pole piece;
82. Second source-drain layer; 821. Second wire; 822. First dummy wire; 823. Second dummy wire; 824. Connection drain;
9. Binding pin;
10. Driving chip; 11. Flexible printed circuit board; 12. First electrode; 13. Pixel definition layer; 14. Light emitting layer group; 15. Second electrode; 16. Encapsulation layer group;
100. Pixel; T, transistor; C, storage capacitor; R, Light emitting device;
AA, Display area; AAL, First side display area; AAI, Middle display area; AAR, Second side display area; FA1, First non-display area; FA2, Second non-display area; ZW, Bending area; BOD, Binding area;
X, First direction; Y, Second direction.

### DETAILED DESCRIPTION

Example embodiments will now be described more fully with reference to the accompanying drawings. However, the example embodiments can be implemented in a variety of forms and should not be construed as being limited to implementations set forth herein; rather, these embodiments are provided so that the present disclosure will be thorough and complete so as to convey the idea of the example embodiments to those skilled in this art. The same reference numerals in the drawings denote the same or similar structures, and the detailed description thereof will be omitted. In addition, the drawings are merely schematic representations of the present disclosure and are not necessarily drawn to scale.

Although the relative terms such as “above” and “below” are used in the specification to describe the relative relationship of one component to another component shown, these terms are only for convenience in this specification, for example, according to an example direction shown in the drawings. It will be understood that if the device shown is flipped upside down, the component described as “above” will become a component “below” another component. When a structure is “on” another structure, it may mean that a structure is integrally formed on another structure, or that a structure is “directly” disposed on another structure, or that a structure is “indirectly” disposed on another structure through other structures.

The terms “one”, “a”, “the”, “said”, and “at least one” are used to indicate that there are one or more elements/components or the like; the terms “include” and “have” are used to indicate an open meaning of including and means that there may be additional elements/components/etc. in addition to the listed elements/components/etc.; and the terms “first”, “second” and “third” etc. are used only as markers, and do not limit the number of objects.

As described above, with the development of technologies, customers have increasingly demanding requirements for display products, thereby constantly promoting to improve screen-to-body ratios and pixel densities of the display products. In order to increase the screen-to-body ratios, it is imperative to narrow bezels of the display products.

However, narrowing the bezels may result in insufficient space to accommodate wires leading from display areas. When the pixel densities are high, there is even less space to accommodate the wires leading from the display areas.

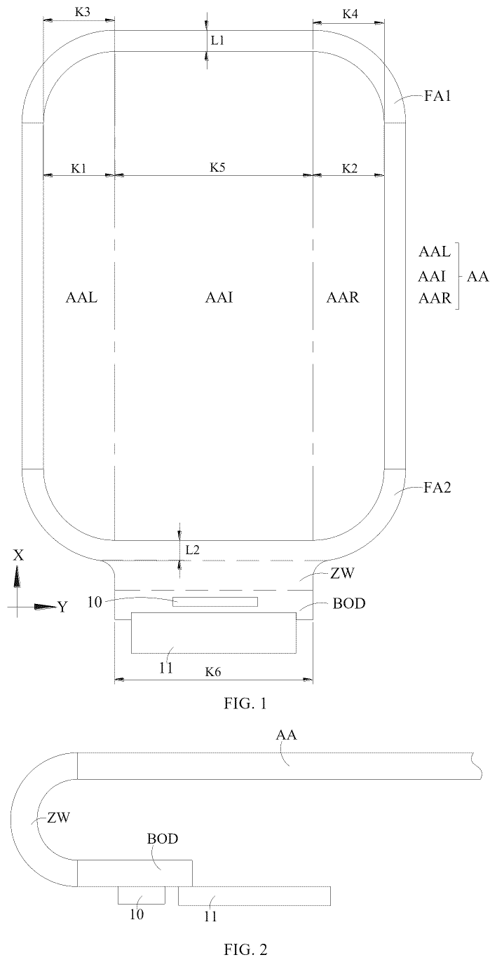

Embodiments of the present disclosure provide a display panel. As shown in FIGS. 1 to 7, the display panel has a display area AA. A first non-display area FA1 and a second non-display area FA2 are correspondingly disposed on opposite sides of the display area AA in a first direction X. A binding area BOD is disposed on a side of the second non-display area FA2 away from the display area AA. The display panel may include a first wire 811, a second wire 821, a connection wire 612 and a binding pin 9. The first wire 811 is disposed in the display area AA and extends along the first direction X. The first wire 811 is electrically coupled to a plurality of pixels 100 arranged along the first direction X. The second wire 821 extends along the first direction X and extends from the display area AA to the first non-display area FA1, the second non-display area FA2 and the binding area BOD. The connection wire 612 is disposed in the first non-display area FA1 and is coupled between the first wire 811 and the second wire 82. The binding pin 9 is disposed in the binding area BOD and is coupled to the second wire 821.

In the display panel of the present disclosure, the first wire 811 and the second wire 821 are coupled through the connection wire 612 disposed in the first non-display area FA1, and the second wire 821 is coupled to the binding pin 9, so as to realize coupling of the first wire 811 with the binding pin 9, and an electrical signal is input or output to the first wire 811 through the binding pin 9, that is, the first wire 811 is led out from the first non-display area FA1. On the one hand, via holes of the connection wire 612 that are coupled with the first wire 811 and the second wire 821 may be disposed in the first non-display area FA1 instead of the display area AA. Even when a pixel density is high, there is enough space to accommodate the via holes of the connection wire 612 that are coupled with the first wire 811 and the second wire 821. On the other hand, the connection wire 612 is not disposed in the second non-display area FA2, which can meet a narrow bezel requirement, so that the display panel meets a narrow bezel design under the high pixel density. On the yet other hand, both the first wire 811 and the second wire 821 extend along the first direction X in the display area AA, without forming a bent structure and then without affecting a display effect of the display panel.

The display panel may be an Organic ElecToluminescence Display (OLED) display panel, a Quantum Dot Light Emitting Diodes (QLED) display panel, etc. The display panel has a light emitting side and a non-light emitting side arranged oppositely. A picture can be displayed on the light emitting side, and a surface displaying the picture is a display surface. The OLED display panel has characteristics of self-illumination, high brightness, wide viewing angle, fast response time, and the ability to produce R, G, and B full-color components, which is regarded as a star product of next-generation displays accordingly.

The following takes the OLED display panel as an example for explanation.

Referring to FIG. 1, the display panel may include the display area AA that displays an image and a peripheral area that does not display the image. The peripheral area may be arranged around the display area AA. The peripheral area may include the first non-display area FA1, the second non-display area FA2, a bending area ZW, and the binding area BOD. The first non-display area FA1 and the second non-display area FA2 are disposed on opposite sides of the display area AA in the first direction X. The binding area BOD is disposed on the side of the second non-display area FA2 away from the display area AA. Specifically, the bending area ZW is coupled to the second non-display area FA2, and the binding area BOD is coupled to the bending area ZW, that is, the bending area ZW is coupled between the bending area ZW and the second non-display area FA2. Referring to FIG. 2, the display panel may be bent at the bending area ZW, so that the binding area BOD is bent on a side of the display area AA away from the display surface.

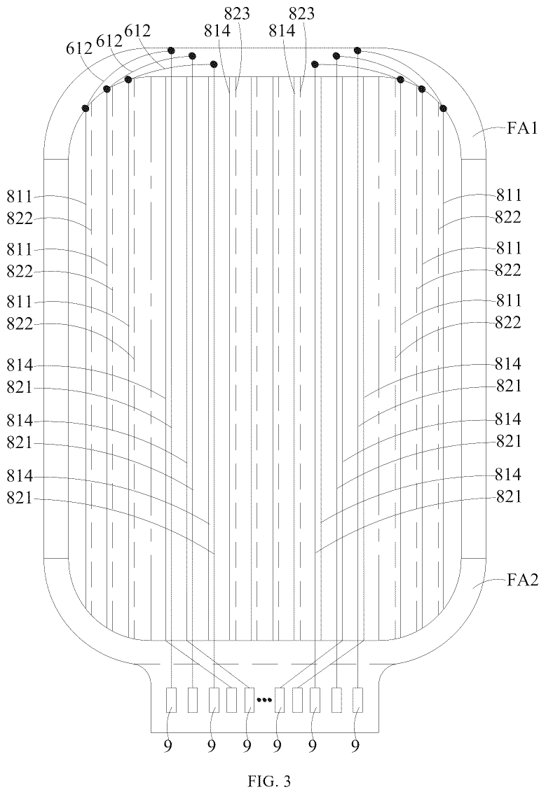

Referring to FIGS. 1 and 3, the binding pin 9 is disposed in the binding area BOD, and an external device may be installed on (or attached to) the binding pin 9. The external device may include a driving chip 10, a flexible printed circuit board 11, a rigid printed circuit board, or the like. In addition, Chip On Flex or Chip On Film (COF), a connector, etc. may also be installed on the binding pin 9 as the external device. One or more external devices may be installed in the binding area BOD. The driving chip 10 may be disposed in the binding area BOD of the display panel, and the printed circuit board may be attached to an end of the binding area BOD. In this case, the display panel may include a binding pin 9 coupled to the driving chip 10 and a binding pin 9 coupled to the printed circuit board. In another embodiment, the driving chip 10 may be installed on the chip-on-film, and the chip-on-film may be attached to the binding area BOD of the display panel.

The driving chip 10 may be installed on the same surface of the display panel as the display surface. When the bending area ZW is bent, the driving chip 10 is located on a side of the display panel away from the display surface.

The driving chip 10 may be bonded to the display panel through anisotropic conductive adhesive, or may be attached to the display panel through ultrasonic bonding. A width of the driving chip 10 in the second direction Y may be smaller than a width of the display panel in the second direction Y. The driving chip 10 may be arranged at a center of the binding area BOD in the second direction Y, and both side edges of the driving chip 10 may be spaced apart from both side edges of the binding area BOD, respectively.

The driving chip 10 may include an integrated circuit that drives the display panel. In embodiments of the present disclosure, the integrated circuit may be a data driving integrated circuit that generates and provides a data signal, but the present disclosure is not limited thereto. The driving chip 10 is coupled to the binding pin 9 of the display panel to provide the data signal to the binding pin 9. A wire coupled to the binding pin 9 extends towards the display area AA to apply the data signal to each pixel 100.

It should be noted that, in order to unify standards, in this specification, dimensions of individual areas and individual devices along the first direction X are lengths, and dimensions of the individual areas and the individual devices along the second direction Y are widths.

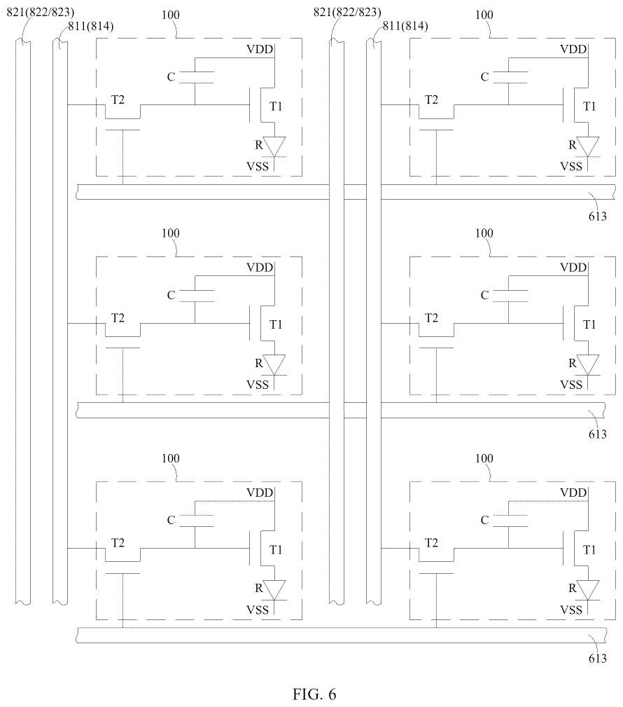

A plurality of pixels 100 may be disposed in the display area AA, and the plurality of pixels 100 may be arranged in a matrix shape. Each pixel 100 may include a light emitting device R and a circuit structure that controls an amount of light emitted from the light emitting device R. The circuit structure may include at least one storage capacitor C and at least one transistor T. Referring to FIG. 6, the circuit structure of the OLED display panel may include one storage capacitor C and at least two transistors T. Alternatively, the circuit structure may also include one storage capacitor C and more transistors T.

Referring to FIG. 6, pixels 100 belonging to the same column may receive the data signal from the same data line (the first wire 811 or a third wire 814), and pixels 100 belonging to the same row may receive a gate signal from the same gate line 613.

It should be noted that an arrangement along the first direction X is called a column, and an arrangement along the second direction Y is called a row.

The circuit structure may include a first transistor T1, a second transistor T2, a storage capacitor C and a light emitting device R. Each pixel 100 is coupled to a scan line (the gate line 613), a data line (the first wire 811 or the third wire 814), and a first power voltage line VDD.

The first transistor T1 may be a driving transistor, and the second transistor T2 may be a switching transistor. Although it is shown in the drawing that both the first transistor T1 and the second transistor T2 are NMOS transistors, one or both of the first transistor T1 and the second transistor T2 may be the PMOS transistor.

A first electrode (i.e., a drain 812) of the first transistor T1 is coupled to the first power voltage line VDD, and a second electrode (i.e., a source 813) of the first transistor T1 is coupled to a pixel electrode (or a first electrode 12) of the light emitting device R. A first electrode (i.e., a source) of the second transistor T2 is coupled to the data line (the first wire 811 or the third wire 814), and a second electrode (i.e., a drain) of the second transistor T2 is coupled to a gate of the first transistor T1. The storage capacitor C is coupled between the first electrode and the gate of the first transistor T1. A common electrode (or a second electrode 15) of the light emitting device R receives a second power voltage VSS. The second power voltage VSS may be a lower voltage than a first power voltage supplied from the first power voltage line VDD.

The second transistor T2 may output a data signal applied to the data line (the first wire 811 or the third wire 814) in response to a scan signal applied to the scan line (the gate line 613). The storage capacitor C may be charged with a voltage corresponding to the data signal received from the second transistor T2. The first transistor T1 may control a driving current flowing through the light emitting device R in response to an amount of charges stored in the storage capacitor C.

A resolution of the display panel may be Quarter High Definition (QHD), which has a resolution of up to 2560×1440, commonly known as 2 k (1440 P) resolution, which is twice the width and height and four times an area of the ordinary HD (1280×720). The higher resolution of the display panel results in the display area AA requiring more wires (the data line, the scan line, etc.) to be led to the binding pin 9 of the binding area BOD through the first non-display area FA1. The binding with the flexible printed circuit board 11 or the coupling with the driving chip 10 is realized in the binding area BOD, thereby realizing signal transmission to the display area AA.

However, in order to achieved a narrow bezel, a length L1 of the first non-display area FA1 and a length L2 of the second non-display area FA2 in the first direction X are both narrow. Furthermore, a corner portion of the display panel is provided with a chamfer, and the chamfer may be a rounded chamfer. Alternatively, the chamfer may also be an oblique chamfer.

In an embodiment of the present disclosure, referring to FIG. 1, the display area AA may include a first side display area AAL, a middle display area AAI and a second side display area AAR coupled in sequence in the second direction Y, that is, the middle display area AAI is coupled between the first side display area AAL and the second side display area AAR in the second direction Y. The middle display area AAI is coupled to the bending area ZW and the binding area BOD, and the first side display area AAL and the second side display area AAR are not coupled to the bending area ZW and the binding area BOD. A width K1 of the first side display area AAL and a width K2 of the second side display area AAR may be the same in the second direction Y. Alternatively, the width K1 of the first side display area AAR and the width K2 of the second side display area AAR may also be different in the second direction Y according to a setting need of the display panel.

A position where the chamfer is disposed is not coupled with the bending area ZW or the binding area BOD, so that in the second direction Y, a width of the binding area BOD is smaller than a width of the display area AA. Specifically, a width K6 of the binding area BOD may be equal to a width K5 of the middle display area AAI.

In the second direction Y, the width K1 of the first side display area AAL is the same as a width K3 of the corresponding chamfer, and the width K2 of the second side display area AAR is the same as a width K4 of the corresponding chamfer. Alternatively, in some other embodiments of the present disclosure, the width K1 of the first side display area AAL may be greater than or less than the width K3 of the corresponding chamfer, and the width K2 of the second side display area AAR may be greater than or less than the width K4 of the corresponding chamfer.

In addition, since the second non-display area FA2 is disposed between the binding area BOD and the display area AA, the first wire 811 extending to the chamfer needs to be bent in the second non-display area FA2 before it can be coupled to the binding area BOD. Moreover, in the first direction X, the length L1 of the first non-display area FA1 is greater than the length L2 of the second non-display area FA2, resulting in the second non-display area FA2 failing to accommodate too many first wires 811.

Alternatively, in some other embodiments of the present disclosure, widths of the bending area ZW and the binding area BOD in the second direction Y may be set to be narrower.

It should be noted that the first non-display area FA1 may include a strip-shaped first part extending along the second direction Y and may also include two strip-shaped second parts disposed on a periphery of the chamfer of the display area AA, and further, the length L1 of the first non-display area FA1 refers to the length L1 of the first part extending along the second direction Y. The second non-display area FA2 may include a strip-shaped third part extending along the second direction Y and may also include two strip-shaped fourth parts disposed on the periphery of the chamfer of the display area AA, and further, the length L2 of the second non-display area FA2 refers to the length L2 of the third part extending along the second direction Y.

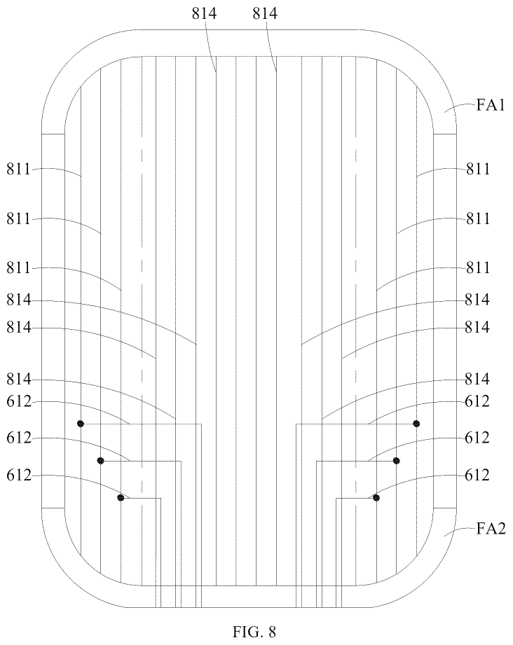

In some embodiments of the present disclosure, referring to FIG. 8, a black dot in the figure represents a connection via hole, and the connection wire 612 is disposed in the display area AA. Moreover, in order to cooperate with the display of the pixels 100 arranged in an array in the display area AA, the connection wire 612 is disposed as a bending structure, and the connection wire 612 extends to a middle of the display area AA and then is bent. An end of the connection wire 612 is coupled to the first wire 811 through the via hole, and the other end of the connection wire 612 is coupled to the binding pin 9, realizing the coupling between the first wire 811 and the binding pin 9 in an edge area. However, due to the large pixel density in the display area AA, it is difficult to provide a position for arranging the via hole, and moreover, the connection wire 612 is disposed as the bending structure in the display area AA, which will affect the display of the display panel and lead to poor display.

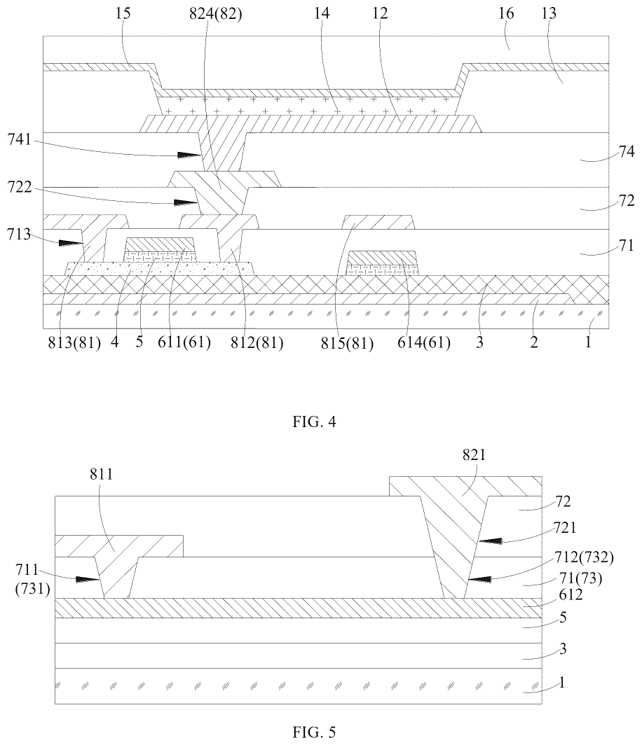

In embodiments of the present disclosure, referring to FIG. 4, the display panel may include a base substrate 1, and a material of the base substrate 1 may include an inorganic material, which may be, for example, glass, quartz, metal or the like. The material of the base substrate 1 may also include an organic material, which may be, for example, a resin material such as polyimide, polycarbonate, polyacrylate, polyetherimide, polyethersulfone, polyethylene terephthalate and polyethylene glycol naphthalate. The base substrate 1 may be formed of a plurality of material layers. For example, the base substrate 1 may include a plurality of base layers, and a material of the base layer may be any of the above materials. Alternatively, the base substrate 1 may also be disposed as a single layer, which may be any of the above materials.

A light shielding layer 2 may also be disposed on a side of the base substrate 1. The light incident from the base substrate 1 into an active layer 4 will generate photogenerated carriers in the active layer 4, which will have a huge impact on a characteristic of the thin film transistor T, ultimately affecting a display quality of the display device. The light incident from the base substrate 1 may be blocked by the light shielding layer 2, thereby avoiding affecting the characteristic of the thin film transistor T and the display quality of the display device.

A buffer layer 3 may also be disposed on a side of the light shielding layer 2 away from the base substrate 1. The buffer layer 3 plays a role in blocking water vapor and impurity ions in the base substrate 1 (especially the organic material), and plays a role in increasing hydrogen ions for the active layer 4 subsequently formed. A material of the buffer layer 3 is an insulation material, which can insulate and isolate the light shielding layer 2 from the active layer 4. The buffer layer 3 may include silicon nitride, silicon oxide, or silicon oxynitride. Depending on a type or a process condition of the base substrate 1, the buffer layer 3 may be omitted.

The active layer 4 is disposed on a side of the buffer layer 3 away from the base substrate 1. The active layer 4 may include a channel portion and conductor portions disposed at both ends of the channel portion. The active layer 4 may include polysilicon. However, the present disclosure is not limited thereto, and the active layer 4 may include single crystal silicon, low-temperature polycrystalline silicon, amorphous silicon, an oxide semiconductor, or the like. The oxide semiconductor may include binary compounds (ABx), ternary compounds (ABxCy) and quaternary compounds (ABxCyDz) each containing indium (In), zinc (Zn), gallium (Ga), tin (Sn), titanium (Ti), aluminum (Al), hafnium (Hf), zirconium (Zr), or magnesium (Mg).

A gate insulation layer 5 is disposed on a side of the active layer 4 away from the base substrate 1. The gate insulation layer 5 may include silicon compound, metal oxide or the like. For example, the gate insulation layer 5 may include silicon oxide, silicon nitride, silicon oxynitride, aluminum oxide, tantalum oxide, hafnium oxide, zirconium oxide, titanium oxide, or the like, which may be used individually or in combination with each other. The gate insulation layer 5 may be a single-layer film or a multi-layer film, and the multi-layer film is formed into a stacked structure of different materials. The gate insulation layer 5 may be disposed only on a side of a first gate layer 61 close to the base substrate 1. Alternatively, the gate insulation layer 5 may also be arranged over the entire surface of the base substrate 1.

The first gate layer 61 is disposed on a side of the gate insulation layer 5 away from the base substrate 1. The first gate layer 61 may include the connection wire 612, the gate 611, the gate line 613 and a first capacitor pole piece 614 of the storage capacitor C. The gate line 613 extends along the second direction Y, and the gate line 613 is coupled to the gate 611, or a part of the gate line 613 may be reused as the gate 611.

The first gate layer 61 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first gate layer 61 may be a single-layer film or a multi-layer film.

In embodiments of the present disclosure, referring to FIGS. 4 and 5, the connection wire 612 may be disposed on the first gate layer 61 and located in the first non-display area FA1. The connection wire 612 may also include one part. Specifically, the connection wire 612 may also be disposed as an arc, and the arc may well match the rounded chamfer of the display panel. Alternatively, in a case that the chamfer of the display panel is the oblique chamfer, the connection wire 612 may be disposed as an oblique line, so that the connection wire 612 matches the oblique chamfer of the display panel.

Alternatively, in some other embodiments of the present disclosure, the connection wire 612 may include two parts, which are specifically a first connection part and a second connection part. The first connection part may extend along the first direction X, and an end of the first connection part is coupled to the first wire 811. The second connection part may extend along the second direction Y, the other end of the first connection part is coupled to an end of the second connection part, and the other end of the second connection part is coupled to the second wire 821. This situation is generally applicable to a case that the display panel is not provided with the chamfer, but is not limited to this situation. In addition, the connection wire 612 may also be disposed as a multi-section bent structure, which will not be described again here.

A first insulation layer 71 is disposed on a side of the first gate 611 away from the base substrate 1. The first insulation layer 71 may include an inorganic insulation material, such as silicon oxide, silicon nitride, silicon oxynitride, hafnium oxide, aluminum oxide, titanium oxide, tantalum oxide or zinc oxide. The first insulation layer 71 may be generally arranged over the entire surface of the base substrate 1.

A first via hole 711 and a second via hole 712 are disposed in the first insulation layer 71. The first via hole 711 is in communication with an end of the connection wire 612, and the second via hole 712 is in communication with the other end of the connection wire 612. Two fourth via holes 713 are disposed in the first insulation layer 71, and the fourth via hole 713 is in communication with the conductor portion.

A first source-drain layer 81 is disposed on a side of the first insulation layer 71 away from the base substrate 1. The first source-drain layer 81 may include the data line, the source 813, the drain 812 and a second capacitor pole piece 815 of the storage capacitor C. The data line extends along the first direction X, and the data line may be coupled to the drain 812 as a whole. The source 813 and the drain 812 are coupled to two conductor portions through the two fourth via holes 713, respectively. The first source-drain layer 81 may include at least one metal selected from aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The first source-drain layer 81 may be a single-layer film or a multi-layer film. For example, the first source-drain layer 81 may be formed to have a stacked structure of Ti/Al/Ti, Mo/Al/Mo, Mo/AlGe/Mo, or Ti/Cu.

In embodiments of the present disclosure, the first source-drain layer 81 may include a plurality of first wires 811 and a plurality of third wires 814. The first wire 811 and the third wire 814 may be data lines, and both the first wire 811 and the third wire 814 extend along the first direction X.

Referring to FIGS. 3 and 6, the plurality of first wires 811 and the plurality of third wires 814 are evenly arranged in the display area AA. A part of the plurality of first wires 811 is disposed in the first side display area AAL, and the other part is disposed in the second side display area AAR. In addition, a column of pixels 100 arranged along the first direction X is disposed between two adjacent first wires 811, that is, one first wire 811 is disposed in a space between two adjacent columns of pixels 100, and the first wire 811 is coupled to drains 812 of a plurality of pixels 100 in the column of pixels 100 on the same side. The plurality of third wires 814 are disposed in the middle display area AAI, and a column of pixels 100 arranged along the first direction X is also disposed between two adjacent third wires 814, that is, one third wire 814 is disposed in a space between two adjacent columns of pixels 100, and the third wire 814 is coupled to drains 812 of a plurality of pixels 100 in the column of pixels 100 on the same side.

The third wire 814 may directly extend from the middle display area AAI to the second non-display area FA2, the bending area ZW and the binding area BOD, and be coupled to the binding pin 9 of the binding area BOD. The first wire 811 cannot be directly coupled to the bending area ZW and the binding area BOD.

A second insulation layer 72 is disposed on a side of the first source-drain layer 81 away from the base substrate 1. The second insulation layer 72 may include an organic insulation material, such as polyacrylate resin, epoxy resin, phenolic resin, polyamide resin, polyimide resin, unsaturated polyester resin, polyphenylene ether resin, polyphenylene sulfide resin, or Benzocyclobutene (BCB). A fifth via hole 722 is disposed in the second insulation layer 72, and the fifth via hole 722 is coupled to the source 813. A third via hole 721 is disposed in the second insulation layer 72, and the third via hole 721 is in communication with the second via hole 712, so that the third via hole 721 is in communication with the other end of the connection wire 612.

A second source-drain layer 82 is disposed on a side of the second insulation layer 72 away from the base substrate 1. The second source-drain layer 82 may include at least one metal selected from aluminum (Al), molybdenum (Mo), platinum (Pt), Palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu). The second source-drain layer 82 may be a single-layer film or a multi-layer film. The second source-drain layer 82 may be made of the same material as the first source-drain layer 81, but the present disclosure is not limited thereto.

The second source-drain layer 82 may include a connection drain 824, the second wire 821, a first dummy wire 822 and a second dummy wire 823, and the connection drain 824 is coupled to the drain 812.

In embodiments of the present disclosure, referring to FIGS. 3, 5 and 6, the black dot in FIG. 3 represents the connection via hole, and the first dummy wire 822 and the second dummy wire 823 are represented by dotted lines. The second source-drain layer 82 may include a plurality of second wires 821, the plurality of second wires 821 are disposed in the middle display area AAI, and a column of pixels 100 arranged along the first direction X is also disposed between two adjacent second wires 821. That is, one second wire 821 is disposed in a space between two adjacent columns of pixels 100. An end of the second wire 821 extends to the first non-display area FA1 and is coupled to an end of the connection wire 612 through the second via hole 712 in the first insulation layer 71 and the third via hole 721 in the second insulation layer 72. The other end of the second wire 821 extends from the middle display area AAI to the second non-display area FA2, the bending area ZW and the binding area BOD, and is coupled to the binding pin 9 of the binding area BOD.

Thus, the first wires 811 located in the first side display area AAL and the second side display area AAR are coupled to the binding pins 9 in the binding area BOD through the connection wire 612 and the second wires 821. On the one hand, the connection wire 612 is not disposed in the display area AA, the second wire 821 is disposed in the display area AA, but the second wire 821 is disposed in a straight shape, therefore, no wires with corners will be formed in the display area AA and the display effect will not be affected. On the other hand, the via holes of the connection wire 612 coupled to the first wire 811 and the second wire 821 are all disposed in the first non-display area FA1, and there are no holes in the display area AA, therefore, there is enough space to dispose the above via hole, which will not be affected by the pixel density of the display panel.

The second wire 821 corresponds to the third wire 814, and the second wire 821 and the third wire 814 are disposed in a staggered manner. An orthographic projection of the second wire 821 on the base substrate 1 is not overlapped with an orthographic projection of the third wire 814 on the base substrate 1, that is, a gap is provided between the orthographic projection of the second wire 821 on the base substrate 1 and the orthographic projection of the third wire 814 on the base substrate 1. A width of the gap is greater than or equal to 1.5 microns and less than or equal to 3.5 microns, which may be, for example, 1.8 microns, 2 microns, 2.5 microns, 2.8 microns, 3 microns, 3.3 microns, etc. Such arrangement can prevent a parasitic capacitance C from being generated between the second wire 821 and the third wire 814 to affect the display of the display panel.

Further, the second source-drain layer 82 may include a plurality of first dummy wires 822 disposed in the display area AA, which are specifically disposed in the first side display area AAL and the second side display area AAR. The first dummy wire 822 extends along the first direction X, and the first dummy wire 822 is disposed in a space between two adjacent columns of pixels 100, that is, one column of pixels 100 is disposed between two adjacent first dummy wires 822. The first dummy wire 822 corresponds to the first wire 811, and the first dummy wire 822 and the first wire 811 are disposed in a staggered manner. An orthographic projection of the first dummy wire 822 on the base substrate 1 is not overlapped with an orthographic projection of the first wire 811 on the base substrate 1, that is, a gap is provided between the orthographic projection of the first dummy wire 822 on the base substrate 1 and the orthographic projection of the first wire 811 on the base substrate 1. A width of the gap is greater than or equal to 1.5 microns and less than or equal to 3.5 microns, which may be, for example, 1.8 microns, 2 microns, 2.5 microns, 2.8 microns, 3 microns, 3.3 microns, etc. Such arrangement can prevent a parasitic capacitance C from being generated between the first dummy wire 822 and the first wire 811 to affect the display of the display panel.

The first dummy wire 822 and the second wire 821 are evenly disposed in the display area AA to avoid only arranging the second wire 821 in the middle display area AAI to affect an overall display effect of the display area AA.

The first dummy wire 822 may be coupled to a power line (VDD), a ground line (VSS), etc.

In a case that in the second direction Y, the sum of the width of the first side display area AAL and the width of the second side display area AAR is substantially equal to the width of the middle display area AAI, the sum of the number of first wires 811 in the first side display area AAL and the number of first wires 811 in the second side display area AAR is substantially equal to the number of third wires 814 in the middle display area AAI. Accordingly, the number of third wires 814 in the middle display area AAI is substantially the same as the number of second wires 821 in the middle display area AAI, so that the first dummy wire 822 and the second wire 821 are evenly disposed in the display area AA.

However, in a case that the sum of the width of the first side display area AAL and the width of the second side display area AAR is smaller than the width of the middle display area AAI, the sum of the number of first wires 811 in the first side display area AAL and the number of first wires 811 in the second side display area AAR is smaller than the number of third wires 814 in the middle display area AAI. In this way, the number of third wires 814 in the middle display area AAI is larger than the number of second wires 821 in the middle display area AAI, and as a result, the second wires 821 cannot be evenly arranged in the middle display area AAI, which affects the overall display effect of the display area AA.

Therefore, the second source-drain layer 82 may also include a second dummy wire 823 disposed in the display area AA, which are specifically disposed in the middle display area AAI. The second dummy wire 823 extends along the first direction X, and the second dummy wire 823 is disposed in a space between two adjacent columns of pixels 100, that is, one column of pixels 100 is disposed between two adjacent second dummy wires 823. The second dummy wire 823 corresponds to the third wire 814, and the second dummy wire 823 and the third wire 814 are disposed in a staggered manner. An orthographic projection of the second dummy wire 823 on the base substrate 1 is not overlapped with the orthographic projection of the third wire 814 on the base substrate 1, that is, a gap is provided between the orthographic projection of the second dummy wire 823 on the base substrate 1 and the orthographic projection of the third wire 814 on the base substrate 1. A width of the gap is greater than or equal to 1.5 microns and less than or equal to 3.5 microns, which may be, for example, 1.8 microns, 2 microns, 2.5 microns, 2.8 microns, 3 microns, 3.3 microns, etc. Such arrangement can prevent a parasitic capacitance C from being generated between the second dummy wire 823 and the third wire 814 to affect the display of the display panel.

The second dummy wire 823 may be coupled to the power line (VDD), the ground line (VSS), etc.

Such arrangement allows the first dummy wire 822, the second dummy wire 823 and the second wire 821 to be evenly disposed in the display area AA, thereby preventing the second wire 821 from being disposed only in a part of the middle display area AAI to affect the overall display effect of the display area AA.

With continued reference to FIG. 4, a fourth insulation layer 74 is disposed on a side of the second source-drain layer 82 away from the base substrate 1. The fourth insulation layer 74 may include the same material as the second insulation layer 72, or may include at least one of the constituent materials of the second insulation layer 72 described above.

The active layer 4, the gate 611, the source 813 and the drain 812 form the thin film transistor T. It should be noted that the thin film transistor T described in this specification is a top-gate thin film transistor T. In other embodiments of the present disclosure, the thin film transistor T may also be a bottom-gate type transistor or a double-gate type transistor, and the specific structure will not be described again. Furthermore, in a case that thin film transistors T with opposite polarities are used or when a current direction changes during the circuit operation, functions of “the source 813” and “the drain 812” may be interchanged with each other. Therefore, in this specification, “the source 813” and “the drain 812” may be interchanged with each other.

A light emitting device R is disposed on a side of the fourth insulation layer 74 away from the base substrate 1. The light emitting device R may include the first electrode 12, a pixel definition layer 13, a light emitting layer group 14 and the second electrode 15.

Specifically, the first electrode 12 is disposed on the side of the fourth insulation layer 74 away from the base substrate 1. The first electrode 12 is coupled to the drain 812 of the driving backplane through a sixth via hole 741. The first electrode 12 may be an anode (the pixel electrode).

The first electrode 12 may have a laminated film structure, and in the laminated film structure, a high work function material layer and a reflective material layer are laminated, and the high work function material layer may include Indium-Tin-Oxide (ITO), Indium-Zinc-Oxide (IZO), zinc oxide (ZnO) or indium oxide (In2O3), the reflective material layer may include silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or a mixture thereof. The high work function material layer may be disposed above the reflective material layer to be closer to the organic layer. The first electrode 12 may have a multi-layer structure of ITO/Mg, ITO/MgF2, ITO/Ag and ITO/Ag/ITO, but the present disclosure is not limited thereto.

The pixel definition layer 13 is disposed on a side of the first electrode 12 away from the base substrate 1. An opening is disposed in the pixel definition layer 13, and the opening exposes the first electrode 12. The pixel definition layer 13 may include an inorganic insulation material such as silicon oxide, silicon nitride, silicon oxynitride, hafnium oxide, aluminum oxide, titanium oxide, tantalum oxide or zinc oxide, or may include an organic insulation material such as polyacrylate resin, epoxy resin, phenolic resin, polyamide resin, polyimide resin, unsaturated polyester resin, polyphenylene ether resin, polyphenylene sulfide resin, or Benzocyclobutene (BCB). The pixel definition layer 13 may be a single-layer film or a multi-layer film, and the multi-layer film is formed as a stack of different materials.

The light emitting layer group 14 is disposed in the opening of the pixel definition layer 13. The light emitting layer group 14 may be made of the inorganic material or the organic material. In embodiments of the present disclosure, the light emitting layer group 14 may include an organic layer, which may, specifically, include a hole injection layer, a hole transport layer, a light emitting layer, an electron transport layer and an electron injection layer stacked in sequence. The hole injection layer is in contact with the first electrode 12, and the electron injection layer is in contact with the second electrode 15. Alternatively, in other embodiments of the present disclosure, the light emitting layer group 14 may only include the hole transport layer, the light emitting layer and the electron transport layer, and the light emitting layer group 14 may also have other structures, and its specific structure may be set as needed.

The second electrode 15 is disposed on a side of the light emitting layer group 14 away from the base substrate 1. The second electrode 15 may be a cathode (the common electrode), and the second electrode 15 is coupled to the ground line VSS. The second electrode 15 may be disposed in a non-light emitting area of the pixel 100 as well as a light emitting area of the pixel 100. That is, the second electrode 15 may be arranged over the entire surface of the plurality of pixels 100. The second electrode 15 may include a low work function material layer containing Li, Ca, LiF/Ca, LiF/Al, Al, Mg, Ag, Pt, Pd, Ni, Au, Nd, Ir, Cr, BaF2, Ba, a compound thereof, or a mixture thereof (e.g., a mixture of Ag and Mg). The second electrode 15 may further include a transparent metal oxide layer disposed on the low work function material layer.

An encapsulation layer group 16 is disposed on a side of the second electrode 15 away from the base substrate 1, and the encapsulation layer group 16 may include an inorganic layer. In embodiments of the present disclosure, the encapsulation layer group 16 may include a first inorganic layer, an organic layer located on a side of the first inorganic layer away from the base substrate 1, and a second inorganic layer located on a side of the organic layer away from the base substrate 1.

In embodiments of the present disclosure, a plurality of first wires 811 are provided. The plurality of first wires 811 are sequentially arranged along the second direction Y, and the plurality of first wires 811 are arranged with serial numbers from the side close to the edge of the display area AA. For example, the plurality of first wires 811 are arranged in sequence with serial numbers I, II, III, IV . . . starting from the side (a left or right side) close to the edge of the display area AA.

A plurality of second wires 821 are provided. The plurality of second wires 821 are sequentially arranged along the second direction Y, and the plurality of second wires 821 are arranged with serial numbers from the side close to the edge of the display area AA. For example, the second wires 821 are arranged in sequence with serial numbers \textcircled{1}, \textcircled{2}, \textcircled{3}, \textcircled{4} . . . starting from the side (the left or right side) close to the edge of the display area AA.

The first wire 811 and the second wire 821 with the same serial number are coupled. Specifically, a first wire 811 with a serial number I is coupled to a second wire 821 with a serial number \textcircled{1}, a first wire 811 with a serial number II is coupled to a second wire 821 with a serial number \textcircled{2}, a first wire 811 with a serial number III is coupled to a second wire 821 with a serial number \textcircled{3}, a first wire 811 with a serial number IV is coupled to a second wire 821 with a serial number \textcircled{4}, etc.

Alternatively, in some other embodiments of the present disclosure, first wires 811 in the first side display area AAL and the second side display area AAR may be arranged with serial numbers, respectively.

For example, in the first side display area AAL, the first wires 811 are sequentially arranged with serial numbers left I, left II, left III, left IV . . . starting from the side close to the edge of the display area AA, and in the second side display area AAR, the first wires 811 are sequentially arranged with serial numbers right I, right II, right III, right IV . . . starting from the side close to the edge of the display area AA.

Accordingly, the plurality of second wires 821 may be divided into two parts. A part of the second wires 821 close to the first side display area AAL is coupled to the first wires 811 in the first side display area AAL, and are arranged with serial numbers starting from the side close to the edge of the display area AA, for example, the second wires 821 are sequentially arranged with serial numbers left \textcircled{1}, left \textcircled{2}, left \textcircled{3}, left \textcircled{4} and so on. The other part of the second wires 821 close to the second side display area AAR is coupled to the first wires 811 in the second side display area AAR, and are arranged with serial numbers starting from the side close to the edge of the display area AA, for example, the second wires 821 are sequentially arranged with serial numbers right \textcircled{1}, right \textcircled{2}, right \textcircled{3}, right \textcircled{4} and so on.

The first wire 811 and the second wire 821 with the same serial number are coupled. Specifically, a first wire 811 with a serial number left I is coupled to a second wire 821 with a serial number left \textcircled{1}, a first wire 821 with a serial number left II is coupled to a second wire 821 with a serial number left \textcircled{2}, a first wire 821 with a serial number left III is coupled to a second wire 821 with a serial number left \textcircled{3}, a first wire 821 with a serial number left IV is coupled to a second wire 821 with a serial number left \textcircled{4}, and so on; a first wire 811 with a serial number right I is coupled to a second wire 821 with a serial number right \textcircled{1}, a first wire 821 with a serial number right II is coupled to a second wire 821 with a serial number right \textcircled{2}, a first wire 821 with a serial number right III is coupled to a second wire 821 with a serial number right \textcircled{3}, a first wire 821 with a serial number right IV is coupled to a second wire 821 with a serial number right \textcircled{4}, and so on.

In embodiments of the present disclosure, a plurality of binding pins 9 are provided. The plurality of binding pins 9 are arranged in the binding area BOD in sequence along the second direction Y, and are arranged with serial numbers from a side close to an edge of the binding area BOD. For example, the plurality of binding pins 9 are arranged in sequence with serial numbers i, ii, iii, iv . . . starting from a side (a left or right side) close to an edge of the binding area BOD.

The second wire 821 and the binding pin 9 with the same serial number are coupled. Specifically, a second wire 821 with a serial number \textcircled{2} is coupled to a binding pin 9 with a serial number i, a second wire 821 with a serial number \textcircled{2} is coupled to a binding pin 9 with a serial number ii, a second wire 821 with a serial number \textcircled{3} is coupled to a binding pin 9 with a serial number iii, a second wire 821 with a serial number \textcircled{4} is coupled to a binding pin 9 with a serial number iv, and so on.

Alternatively, in a case that the first wires 811 in the first side display area AAL and the first wires 811 in the second side display area AAR are arranged with serial numbers, respectively, the plurality of binding pins 9 may also be divided into two parts. A specific arrangement rule and coupling relationship will not be explained one by one.

In addition, the third wire 814 located in the middle display area AAI is coupled to the binding pin 9 in the middle part, and the coupling between the third wire 814 and the binding pin 9 in the middle part is also performed in sequence according to an arrangement order. That is, the third wires 814 are arranged with serial numbers starting from the side close to the edge of the display area AA, the binding pins 9 in the middle part are arranged with serial numbers starting from the side close to the edge of the binding area BOD, and the third wire 814 and the binding pin 9 in the middle part with the same serial number are coupled.

Moreover, since the third wire 814 and the second wire 821 are disposed on different conductive layers, the third wire 814 and the second wire 821 may be alternatively disposed in order to ensure that the third wire 814 and the second wire 821 are coupled to the binding pins 9 according to the above rule. Alternatively, in some other embodiments of the present disclosure, in consideration of ensuring resistances, capacitances, etc. of the first wire 811, the third wire 814 and the second wire 821, parts of the third wire 814 and the second wire 821 located in the second non-display area FA2 may be bent, which will not be described again here.

The driving chip 10 drives the pixels 100 in sequence one column by one column, generally starting from a side edge of the display area AA, and such arrangement enables that a first column of pixels 100 in the display area AA is coupled to a first binding pin 9, a second column of pixels 100 is coupled to a second binding pin 9, a third column of pixel 100 is coupled to a third binding pin 9, . . . , and an order of data signals has not changed, which is convenient for the driving chip 10 to sequentially drive the plurality of pixels 100.

In addition, a plurality of connection wires 612 are not intersected with each other. For example, the plurality of connection wires 612 may be arranged in parallel with each other, so that a connection wire 612 coupled to the outermost first wire 811 is also located at the outermost of the first non-display area FA1, and accordingly, the second wire 821 coupled to the outermost connection wire 612 has the longest length in the first non-display area FA1, and the outermost second wire 821 is coupled to the outermost connection wire 612, so that lengths of the plurality of second wires 821 in the first non-display area FA1 decrease as a distance from the edge of the display area AA in the second direction Y increases.

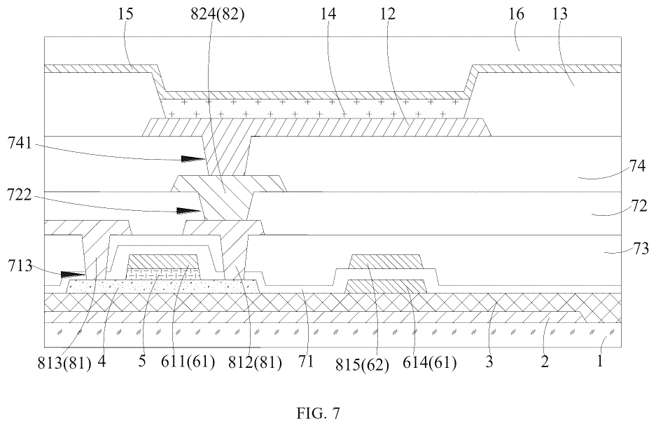

Referring to FIGS. 5 and 7, in some other embodiments of the present disclosure, the display panel may further include a second gate layer 62 and a third insulation layer 73. The second gate layer 62 is disposed on the side of the first insulation layer away from the base substrate, and includes the connection wire, that is, the connection wire may be disposed on the second gate layer 62. The third insulation layer 73 is disposed on a side of the second gate layer 62 away from the base substrate, and the first source-drain layer is disposed on a side of the third insulation layer 73 away from the base substrate.

With such arrangement, a seventh via hole 731 and an eighth via hole 732 are disposed on the third insulation layer 73. The seventh via hole 731 is in communication with an end of the connection wire 612, and the eighth via hole 732 is in communication with the other end of the connection wire 612. The first wire is coupled to the end of the connection wire through the seventh via hole 731. The third via hole 721 disposed in the second insulation layer 72 is in communication with the eighth via hole 732, so that the third via hole 721 is in communication with the other end of the connection wire 612. The second wire is coupled to the other end of the connection wire through the second via hole 712 and the third via hole 721.

A touch layer group may also be disposed on a side of the encapsulation layer group 16 away from the base substrate 1, and a specific structure of the touch layer group will not be described again here. A polarizer, a cover plate, etc. may also be stacked in sequence on a side of the touch layer group away from the base substrate 1.

Based on the same inventive concept, embodiments of the present disclosure provide a display device, which may include any of the above-mentioned display panels. A specific structure of the display panel has been described in detail above, and therefore will not be described again here.

A specific type of the display device is not particularly limited. Any type of the display device commonly used in the field can be used, such as a mobile device such as a mobile phone, a wearable device such as a watch, a VR device, etc. Those skilled in the art can make corresponding selections based on a specific use of the display device, which will not be described again here.

It should be noted that, in addition to the display panel, the display device further includes other necessary components. Taking a display as an example, a housing, a circuit board, a power line, and the like may be included. Those skilled in the art can make corresponding supplements according to the specific usage requirements of the display device, which will not be repeated here.

Compared with the prior art, the beneficial effects of the display device provided by embodiments of the present disclosure are the same as the beneficial effects of the display panel provided by the above embodiments, and will not be described again here.

Other embodiments of the present disclosure will be apparent to those skilled in the art from consideration of the specification and practice of the present disclosure disclosed herein. The present application is intended to cover any variations, uses, or adaptations of the present disclosure, which are in accordance with the general principles of the present disclosure and include common general knowledge or conventional technical means in the art that are not disclosed in the present disclosure. The specification and embodiments are illustrative, and the real scope and spirit of the present disclosure is defined by the appended claims.

1. A display panel with a display area, wherein a first non-display area and a second non-display area are correspondingly disposed on opposite sides of the display area in a first direction, and a binding area is disposed on a side of the second non-display area away from the display area, and wherein the display panel comprises:
a first wire, disposed in the display area and extended along the first direction, wherein the first wire is electrically coupled to a plurality of pixels arranged along the first direction;
a second wire, extended along the first direction and extended from the display area to the first non-display area, the second non-display area and the binding area;
a connection wire, disposed in the first non-display area and coupled between the first wire and the second wire; and
a binding pin, disposed in the binding area and coupled to the second wire.

2. The display panel according to claim 1, wherein:
a plurality of first wires are provided, and the plurality of first wires are sequentially arranged along a second direction and are arranged with serial numbers starting from a side close to an edge of the display area;
a plurality of second wires are provided, and the plurality of second wires are sequentially arranged along the second direction and are arranged with serial numbers starting from the side close to the edge of the display area; and
the first wire and the second wire with the same serial number are coupled, and the second direction is intersected with the first direction.

3. The display panel according to claim 2, wherein:
a plurality of binding pins are provided, and the plurality of binding pins are sequentially arranged in the binding area along the second direction and are arranged with serial numbers starting from a side close to an edge of the binding area; and
the second wire and the binding pin with the same serial number are coupled.

4. The display panel according to claim 2, wherein a plurality of first wires, a plurality of second wires and a plurality of connection wires are provided, and a length of the second wire in the first direction within the first non-display area decreases as a distance from the edge of the display area in the second direction increases.

5. The display panel according to claim 1, wherein the display panel further comprises:
a base substrate;
a first gate layer, disposed on a side of the base substrate and comprising a gate and a gate line, wherein the gate line is extended along a second direction, and the second direction is intersected with the first direction;
a first insulation layer, disposed on a side of the first gate layer away from the base substrate;
a first source-drain layer, disposed on a side of the first insulation layer away from the base substrate and comprising a source, a drain and a data line, wherein the data line is extended along the first direction, and the first wire is the data line;
a second insulation layer, disposed on a side of the first source-drain layer away from the base substrate; and
a second source-drain layer, disposed on a side of the second insulation layer away from the base substrate.

6. The display panel according to claim 5, wherein the second source-drain layer comprises the second wire.

7. The display panel according to claim 6, wherein:
the first gate layer further comprises the connection wire, and a first via hole and a second via hole are disposed in the first insulation layer;
the first via hole is in communication with an end of the connection wire, and the first wire is coupled to the end of the connection wire through the first via hole;
the second via hole is in communication with the other end of the connection wire, a third via hole in communication with the second via hole is disposed in the second insulation layer, and the second wire is coupled to the other end of the connection wire through the second via hole and the third via hole; and
the first via hole, the second via hole and the third via hole are all disposed in the first non-display area.

8. The display panel according to claim 5, wherein the display panel further comprises:
a second gate layer, disposed on the side of the first insulation layer away from the base substrate, and comprising the connection wire; and
a third insulation layer, disposed on a side of the second gate layer away from the base substrate, wherein the first source-drain layer is disposed on a side of the third insulation layer away from the base substrate.

9. The display panel according to claim 1, wherein:
the display area comprises a first side display area, a middle display area, and a second side display area sequentially arranged along a second direction;
the middle display area is coupled to the binding area, and the second direction is intersected with the first direction; and
first wires are disposed in the first side display area and the second side display area, and the second wire is disposed in the middle display area.

10. The display panel according to claim 9, wherein the display panel further comprises:
first dummy wires, disposed in the first side display area and the second side display area and extended along the first direction, wherein the first dummy wires are comprised in a same conductive layer as the second wire; and
the first dummy wires and the first wire are correspondingly disposed in a gap between two adjacent pixel columns, and a pixel column is a plurality of pixels arranged along the first direction.

11. The display panel according to claim 10, wherein the display panel further comprises:
a third wire, disposed in the middle display area, extended along the first direction and extended from the middle display area to the second non-display area and the binding area, and coupled to the binding pin, wherein the third wire is comprised in a same conductive layer as the first wire; and the second wire and at least part of third wires are correspondingly disposed in the gap between the two adjacent pixel columns.

12. The display panel according to claim 11, wherein the display panel further comprises:
a second dummy wire, disposed in the middle display area and extended along the first direction, wherein the second dummy wire is comprised in a same conductive layer as the second wire, and the second dummy wire and a part of the third wires are correspondingly disposed in the gap between the two adjacent pixel columns.

13. The display panel according to claim 12, wherein:
an orthographic projection of a first dummy wire on the base substrate is not overlapped with an orthographic projection of the first wire on the base substrate;
an orthographic projection of the second wire on the base substrate is not overlapped with an orthographic projection of the third wire on the base substrate; and
an orthographic projection of the second dummy wire on the base substrate is not overlapped with the orthographic projection of the third wire on the base substrate.

14. The display panel according to claim 9, wherein in the second direction, a width of the binding area is smaller than a width of the display area.

15. The display panel according to claim 14, wherein:
the display panel has a corner portion, the corner portion is provided with a chamfer, and the first wire is extended to the chamfer;
in the second direction, a width of the first side display area is the same as a width of a corresponding chamfer, and a width of the second side display area is the same as a width of a corresponding chamfer; and
the width of the binding area is equal to a width of the middle display area.

16. The display panel according to claim 1, wherein the connection wire is disposed as an arc or an oblique line.

17. The display panel according to claim 1, wherein the connection wire comprises:
a first connection part, extended along the first direction, wherein an end of the first connection part is coupled to the first wire; and
a second connection part, extended along a second direction, wherein an end of the second connection part is coupled to the other end of the first connection part, the other end of the second connection part is coupled to the second wire, and the second direction is intersected with the first direction.

18. A display device, comprising a display panel with a display area, wherein a first non-display area and a second non-display area are correspondingly disposed on opposite sides of the display area in a first direction, and a binding area is disposed on a side of the second non-display area away from the display area. and wherein the display panel comprises:
a first wire, disposed in the display area and extended along the first direction, wherein the first wire is electrically coupled to a plurality of pixels arranged along the first direction;
a second wire, extended along the first direction and extended from the display area to the first non-display area, the second non-display area and the binding area;
a connection wire, disposed in the first non-display area and coupled between the first wire and the second wire; and
a binding pin. disposed in the binding area and coupled to the second wire.

19. The display device according to claim 18, wherein:
a plurality of first wires are provided, and the plurality of first wires are sequentially arranged along a second direction and are arranged with serial numbers starting from a side close to an edge of the display area;
a plurality of second wires are provided, and the plurality of second wires are sequentially arranged along the second direction and are arranged with serial numbers starting from the side close to the edge of the display area; and
the first wire and the second wire with the same serial number are coupled, and the second direction is intersected with the first direction.

20. The display device according to claim 19, wherein:
a plurality of binding pins are provided, and the plurality of binding pins are sequentially arranged in the binding area along the second direction and are arranged with serial numbers starting from a side close to an edge of the binding area; and
the second wire and the binding pin with the same serial number are coupled.
